(19) United States
(12) Patent Application Publication
(10) Pub. No.: US 2003/0042938 A1
(43) Pub. Date: Mar. 6, 2003

(54) Equivalent shottky or emanuil shvarts diode (ESD)

(76) Inventor: Emanuil Y. Shvarts, Vista, CA (US)

Correspondence Address: HARNESS, DICKEY & PIERCE, P.L.C., P.O. BOX 8910, RESTON, VA, 20195, US

(21) Appl. No.: 09/946,681

(22) Filed: Sep. 6, 2001

(51) Int. Cl. H03B 1/00

(52) U.S. Cl. 327/108

(57) ABSTRACT

The ESD (Equivalent Shottky Diode, or Emanuil Shvarts Diode) includes a transistor and a sensing circuit, which senses a voltage difference across the ESD. A driving circuit controls the operation of the transistor based on the sensed difference.

### BACKGROUND OF THE INVENTION

1. Field the Invention

The present invention is related to power electronic devices. In particular, the present invention relates to a power diode equivalent having a low voltage drop and a method thereof.

2. Description of Related Art

Power diodes find a variety of uses in modern electronic hardware, including wireless communications equipment. Widely known traditional power diodes such as, for example, a Shottky Diode and the like may be used, for example, for power conversion and rectifying from AC to DC, power control and distribution, and the like.

Problems arise however in conventional systems which employ power diodes in that such diodes have significant voltage drop. It is typical for a power diode to drop up to one volt for a regular diode and up to half a volt for a Shottky diode. Such power drops are problematic particularly for mobile handsets where power conservation is an extremely important consideration for preserving battery life. Voltage drop is even more important for contemporary low-voltage applications (3.3 v or 2.5 v). For example, a 0.5 v voltage drop in a 2.5 v supply line means a 20% power loss.

Accordingly, a continuing demand exists in the art for a power diode circuit capable of dissipating less power.

### SUMMARY OF THE INVENTION

A method and apparatus are described for providing a power diode equivalent having a very low voltage drop. The method and apparatus of the present invention result in 10-100 times decrease in the voltage drop and resulting power dissipation by using a device named “ESD” (which stands for Equivalent Shottky Diode, or Emanuil Shvarts Diode).

Thus in accordance with various exemplary embodiments, a difference between an input voltage and an output voltage across a power diode equivalent (e.g., a transistor) is sensed, for example by a comparator. Using the output of this comparator, the transistor is biased in a conductive area (which corresponds to ON state of a diode), or in non-conductive area (which corresponds to OFF state of the diode). The transistor, in accordance with various exemplary embodiments of the present invention, is preferably a n-channel MOSFET. Alternatively the power diode equivalent may be a p-channel MOSFET, or bipolar transistor.

### BRIEF DESCRIPTION OF THE DRAWINGS

The present invention will become more fully understood from the detailed description given hereto below in the accompanying drawings, which are given by way of illustration only, and thus are not limitative of the present invention, and wherein:

FIG. 1 is a schematic diagram illustrating a power diode equivalent circuit in accordance with various exemplary embodiments of the present invention;

FIG. 2 is a schematic diagram further illustrating a power diode equivalent circuit in accordance with various exemplary embodiments of the present invention;

FIG. 3 is a schematic diagram further illustrating a power diode equivalent circuit in accordance with various exemplary embodiments of the present invention;

FIG. 4 is a schematic diagram further illustrating a power diode equivalent circuit in accordance with various exemplary embodiments of the present invention;

FIG. 5 is a schematic diagram further illustrating a power diode equivalent circuit in accordance with various exemplary embodiments of the present invention; and

FIG. 6 is a schematic diagram still further illustrating a power diode equivalent circuit in accordance with various exemplary embodiments of the present invention.

### DETAILED DESCRIPTION OF THE PREFERRED EMBODIMENTS

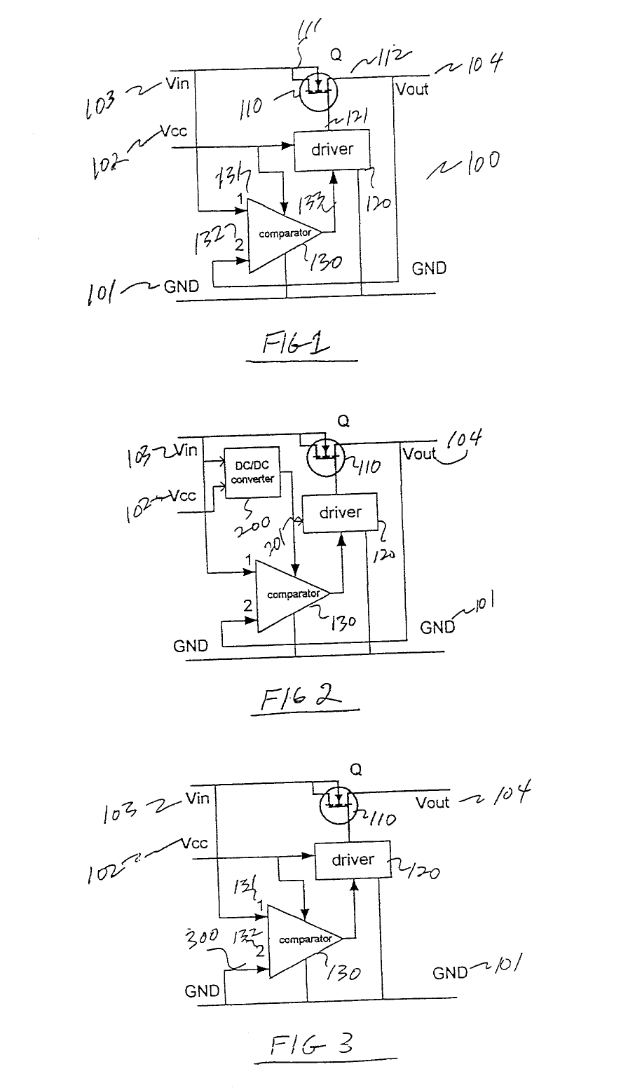

Thus in accordance with various exemplary embodiments of the present invention a power diode equivalent circuit will be described, which circuit possesses desirable characteristics, specifically, a low voltage drop. As can be seen in FIG. 1, the Equivalent Shottky Diode (ESD) basic circuit is illustrated where Vin 103 is the input voltage, Vout 104 is the output voltage, Vcc 102 is the supply source voltage, GND 101 is the ground, and Q 110 is an n-type MOSFET transistor.

In operation in accordance with one preferred exemplary embodiment, comparator 130 senses the voltage difference between Vin 103 and Vout 104 at first and second terminals 131 and 132. A positive voltage between the first and second terminals 131 and 132 results in an output voltage at output 133 of comparator 130, which is input to a driver 120. Driver 120 produces a positive bias at output 121, which is supplied to the gate of transistor 110. Accordingly, transistor 110 will become conductive as a result of the positive difference between Vin 103 and Vout 104, which corresponds to ON state of the ESD. If Vin 103 is less than Vout 104, the transistor 110 will be driven to the off condition by driver 120 so that no output will be produced at output 121 and thus the gate of the transistor 110, which places the ESD in the OFF state. It should be noted that the external voltage Vcc 102, which powers comparator 130 and driver 120, should be larger than the maximum value of Vin 103.

An alternative to providing Vcc 102 as an external supply source is illustrated in FIG. 2.

As shown in FIG. 2, an internal DC/DC converter 200 receives inputs from both Vcc 102 and Vin 103, and output voltage 201 is generated and provided to driver 120 and comparator 130. It should be noted that DC/DC converter 200 is preferably a charge pump doubler or tripler, step up converter, or the like well-known in the art. While input to DC/DC converter 200 is shown as being Vcc 102 and Vin 103, the input may also be derived from only one or the other of Vcc 102 and Vin 103. Use of DC/DC converter 200 is advantageous when a reliable and stable source of a high bias voltage is not available.

An alternative exemplary embodiment is illustrated in FIG. 3. As compared to the embodiment of FIG. 1, the comparator 130 has the second input 132 coupled to ground 101 rather than to Vout 104. The effect of connecting the second input 132 of comparator 130 to ground 101 is that the transistor 110 will be biased on whenever Vin 103 is positive with respect to ground 101. The transistor 110 will also be biased off when Vin 103 is negative with respect to ground 101.

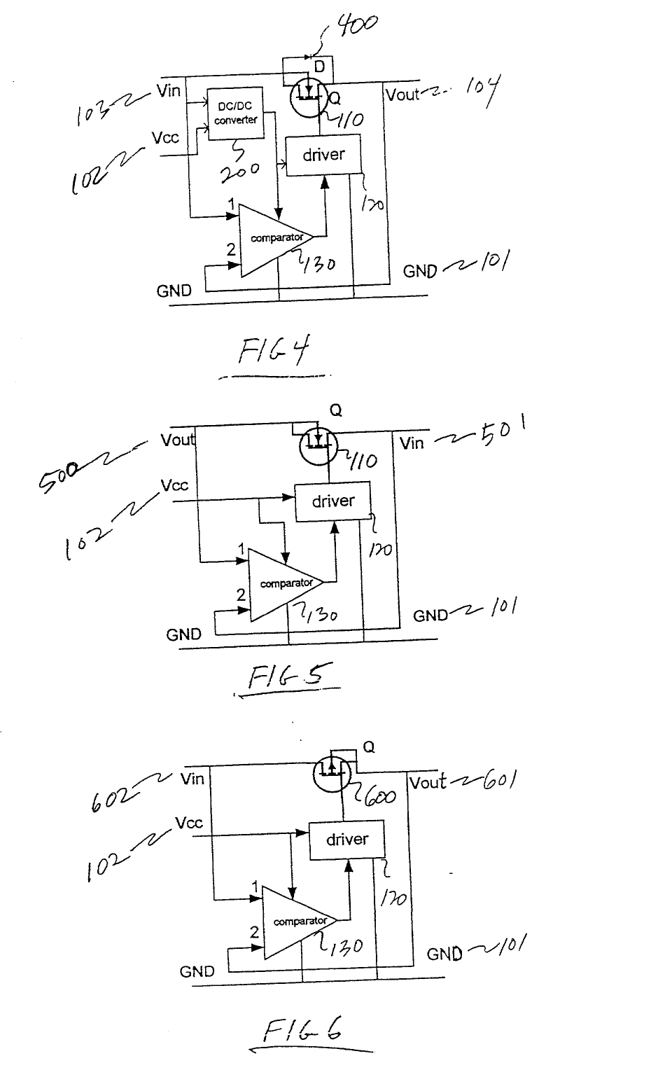

FIG. 4 illustrates adding diode 400, which is a regular diode, for example, a Shottky Diode or the like. By adding diode 400 in parallel with the transistor 110, dynamic performance is improved especially with regard to high frequency signals associated with Vin 103. Moreover, Diode 400 may partially compensate for any delay associated with comparator 130, driver 120, and the transistor 110 during signal transitions. In this case, during the transition time, diode 400 will provide rectification. Because the transition time is very low, around nanoseconds, the associated power losses will be minimal.

If it is desired to produce negative rectification, then as illustrated in FIG. 5, the drain of the transistor 110 is connected to Vin 501. Accordingly, Vout 500 is connected to the source of the transistor 110 resulting in a circuit which is similar in many regards to FIG. 1 through FIG. 4 in terms of biasing the transistor 110 as described.

When an additional supply source with a voltage higher than Vin is not available, a p-type MOSFET 600 may preferably replace transistor 110 such as illustrated in FIG. 6. In this case, an internal step-up converter is not required, and the device gains in simplicity and efficiency. It should be noted that a p-type MOSFET may have substantially worse on-resistance, but an additional supply voltage can be less than Vin 602. It should further be noted that the p-type MOSFET may be substituted for the n-type MOSFET 100 shown in FIGS. 1-5 with appropriate adjustments to biasing values and the like.

In accordance with the various exemplary embodiments of the present invention, the difference between, for example, Vin 103 and Vout 104 may be very small, and for practical purposes comparator 130 will have a non-zero threshold. Accordingly, the transistor 110 will become conductive when Vin 103 minus Vout 104 is greater than or equal to the threshold voltage of comparator 130, e.g. 50 mV. It should be noted that all existing traditional diodes also have a threshold, around 0.2-0.4v. For the suggested ESD, the threshold voltage is adjustable, which is a definite advantage.

The invention being thus described, it will be obvious that one skilled in the art can contemplate several variations thereto. Such variations are not to be regarded as a departure from the invention, and all such modifications are intended to be included within the scope of the following claims.

What is claimed is:

1. A power diode equivalent, comprising:
a transistor;
a sensing circuit sensing a voltage difference across the transistor; and
a driving circuit controlling operation of the transistor based on the sensed voltage difference.

2. The power diode equivalent of claim 1, wherein the driving circuit drives the transistor in a conducting state until the voltage difference is less than or equal to a predetermined threshold.

3. The power diode equivalent of claim 1, wherein the sensing circuit includes a comparator having inputs connected to an input and an output of the transistor.

4. The power diode equivalent of claim 1, further comprising:
an internal integrated power source providing a supply voltage to the comparator and the driving circuit, the supply voltage being maintained greater than the input voltage.

5. The power diode equivalent of claim 1, further comprising:
a diode connected in parallel with the transistor.

6. The power diode equivalent of claim 1, wherein the transistor is a p-channel MOSFET.

7. The power diode equivalent of claim 1, wherein the transistor is a n-channel MOSFET.

8. A method of providing a power diode equivalent, comprising:
sensing a voltage difference across a transistor; and
controlling operation of the transistor based on the sensed voltage difference.

9. The method of claim 8, wherein the controlling step puts the transistor in a conducting state until the sensed voltage difference is less than or equal to a predetermined threshold.

10. The method of claim 8, further comprising:
compensating for delay in the power diode equivalent circuit by connecting a regular diode in parallel with the transistor.
